(19) United States
(12) Patent Application Publication
(10) Pub. No.: US 2025/0022122 A1
(43) Pub. Date: Jan. 16, 2025

(54) METHODS OF DETECTING A CRACK IN A SEMICONDUCTOR ELEMENT, AND RELATED WIRE BONDING SYSTEMS

(71) Applicant: Kulicke and Soffa Industries, Inc., Fort Washington, PA (US)

(72) Inventors: Aashish Shah, Chalfont, PA (US); Wei Qin, Ambler, PA (US)

(73) Assignee: Kulicke and Soffa Industries, Inc., Fort Washington, PA (US)

(21) Appl. No.: 18/766,806

(22) Filed: Jul. 9, 2024

Related U.S. Application Data
(60) Provisional application No. 63/526,054, filed on Jul. 11, 2023.

(51) Int. Cl. G06T 7/00; G01N 21/95; G01R 27/16; H01L 23/00

(52) U.S. Cl. CPC G06T 7/001; G01N 21/9505; G01R 27/16; G06T 2207/30148; H01L 24/78; H01L 2224/78901

(57) ABSTRACT

A method of detecting a crack in a semiconductor element on a wire bonding system is provided. The method includes the steps of: (a) providing a semiconductor element on a wire bonding system; and (b) detecting if there is a crack in the semiconductor element on the wire bonding system.

### CROSS-REFERENCE TO RELATED APPLICATION

This application claims the benefit of U.S. Provisional Application No. 63/526,054, filed Jul. 11, 2023, the content of which is incorporated herein by reference.

### FIELD

The invention relates to methods of detecting a crack in a semiconductor element and to related wire bonding systems.

### BACKGROUND

In the electronics assembly industry, wire bonding continues to be a primary method of providing electrical interconnection between two (or more) locations within a workpiece. In a typical wire bonding application, a wire bonding tool (e.g., a capillary bonding tool in a ball bonding application, a wedge bonding tool in a wedge bonding application, etc.) is used to bond a first end of wire to a first bonding location to form a first bond. Then, a length of wire continuous with the first bond is extended toward a second bonding location. Then, a second bond (continuous with the first bond and the length of wire) is formed at the second bonding location. Thus, a wire loop is formed between the first bonding location and the second bonding location. During formation of wire bonds, various types of energy (e.g., ultrasonic, thermosonic, thermocompressive, etc.) may be used, in connection with bond force and/or heat.

The formation of a crack in a semiconductor element (e.g., a semiconductor die) is a concern in the electronics assembly industry. The formation of such a crack is often a concern in connection with an overhang die (e.g., an unsupported portion of a semiconductor die in a semiconductor device). However, cracking can occur in any type of semiconductor package or device.

U.S. Pat. Nos. 10,121,759 and 10,665,564 (both entitled “ON-BONDER AUTOMATIC OVERHANG DIE OPTIMIZATION TOOL FOR WIRE BONDING AND RELATED METHODS”) relate to techniques for optimizing wire bonding operations in connection with unsupported portions of a semiconductor device (e.g., an overhang die).

Unfortunately, the presence and/or formation of a crack in a semiconductor element often remains undetected until time and/or effort has been wasted in connection with the semiconductor element (e.g., performing wire bonding operations in connection with the semiconductor element). Thus, it would be desirable to improve crack detection of semiconductor elements.

### SUMMARY

According to an exemplary embodiment of the invention, a method of detecting a crack in a semiconductor element on a wire bonding system is provided. The method includes the steps of: (a) providing the semiconductor element on the wire bonding system; and (b) detecting if there is a crack in the semiconductor element on the wire bonding system.

According to other embodiments of the invention, the method recited in the immediately preceding paragraph may have any one or more of the following features: step (b) includes determining a z-axis position of a portion of the semiconductor element to detect if there is a crack in the semiconductor element; step (b) includes performing an imaging operation on the wire bonding system to detect if there is a crack in the semiconductor element; step (b) includes determining a z-axis position of a deflected portion of the semiconductor element to detect if there is a crack in the semiconductor element; step (b) includes determining a z-axis position of a portion of the semiconductor element during a wire bonding operation to detect if there is a crack in the semiconductor element; step (b) includes performing an imaging operation on the wire bonding system to detect if there is a crack in the semiconductor element; the imaging operation includes imaging of a portion of the semiconductor element (i) before formation of a wire bond on the semiconductor element, and (ii) after formation of the wire bond on the semiconductor element; step (b) includes monitoring an electrical characteristic related to ultrasonic energy applied during a wire bonding operation to detect if there is a crack in the semiconductor element; the electrical characteristic is an impedance value related to operation of an ultrasonic transducer; step (b) includes detecting if there is a crack in the semiconductor element using a first bond head assembly of the wire bonding system, the method further including the step of (c) bonding a wire to the semiconductor element using a second bond head assembly of the wire bonding system; and/or step (b) includes contacting a deflected portion of the semiconductor element with a contact tool carried by the first bond head assembly to detect if there is a crack in the semiconductor element.

According to another exemplary embodiment of the invention, a wire bonding system is provided. The wire bonding system includes a bond head assembly configured for carrying a wire bonding tool for performing a wire bonding operation with respect to a workpiece including a semiconductor element. The wire bonding system also includes a support structure for supporting the workpiece. The wire bonding system also includes a computer system. The computer system is configured to detect if there is a crack in the semiconductor element on the wire bonding system.

According to other embodiments of the invention, the wire bonding system recited in the immediately preceding paragraph may have any one or more of the following features: another bond head assembly, wherein the another bond head assembly is configured to carry a contact tool used in connection with detecting if there is a crack in the semiconductor element; the another bond head assembly is configured to carry an imaging system used in connection with detecting if there is a crack in the semiconductor element; the computer system is configured to determine a z-axis position of a portion of the semiconductor element to detect if there is a crack in the semiconductor element; an imaging system attached to the bond head assembly, the imaging system being configured to perform an imaging operation on the wire bonding system in connection with detecting if there is a crack in the semiconductor element; the imaging system is configured for imaging a portion of the semiconductor element (i) before formation of a wire bond on the semiconductor element, and (ii) after formation of the wire bond on the semiconductor element; the computer system is configured to determine a z-axis position of a deflected portion of the semiconductor element to detect if there is a crack in the semiconductor element; the computer system is configured to determine a z-axis position of a portion of the semiconductor element during a wire bonding operation to detect if there is a crack in the semiconductor element; the computer system is configured to monitor an electrical characteristic related to ultrasonic energy applied during a wire bonding operation; and/or the electrical characteristic is an impedance value related to operation of an ultrasonic transducer.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1C are block diagram side views of a portion of a wire bonding system in accordance with an exemplary embodiment of the invention;

FIG. 2 is a timing diagram illustrating a z-axis profile of a portion of a bond head assembly of a wire bonding system during formation of wire bond, useful in connection with various exemplary embodiments of the invention;

FIGS. 3A-3B are graphical illustrations of bonding force versus die deflection in connection with an uncracked semiconductor element, and a cracked semiconductor element, useful in connection with various exemplary embodiments of the invention;

FIGS. 4A-4D and FIGS. 5A-5D are block diagram side and top views of portions of another wire bonding system in accordance with an exemplary embodiment of the invention;

FIGS. 6A-6B are timing diagrams illustrating electrical characteristics related to ultrasonic energy applied during a wire bonding operation, useful in connection with various exemplary embodiments of the invention;

FIG. 7 is a block diagram side view of a portion of yet another wire bonding system in accordance with an exemplary embodiment of the invention; and

FIG. 8 is a flow diagram illustrating a method of detecting a crack in a semiconductor element on a wire bonding system in accordance with various exemplary embodiments of the invention.

### DETAILED DESCRIPTION

As used herein, the term “semiconductor element” is intended to refer to any structure including (or configured to include at a later step) a semiconductor chip or die. Exemplary semiconductor elements include a substrate (e.g., a leadframe, a PCB, a carrier, etc.), a substrate carrying one or more semiconductor die, a bare semiconductor die, a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.).

As used herein, the term “crack” can refer to any undesired irregular condition of a semiconductor element (e.g., a semiconductor die) configured to be wire bonded. For example, a crack may refer to a permanent or plastic deformation in a semiconductor die, such as a die splitting (partially or completely) or an indentation being formed in the die. In another example, the crack may be a fracture and/or a void in a semiconductor die. In yet another example, the crack may be a missing portion of a semiconductor die.

As used herein, the term “electrical characteristic” can refer to an impedance value, a voltage value, a current value, a power draw, and the like.

In accordance with certain exemplary embodiments of the invention, methods and systems of detecting a crack in a semiconductor element (e.g., a semiconductor die) on a wire bonding system are provided. Certain exemplary methods for detecting such a crack on a wire bonding machine may be performed in real time.

In certain exemplary embodiments of the invention, methods of detecting if a crack is present in a semiconductor element include measuring deflection (e.g., using a z-axis encoder of a wire bonding system) of a portion of a semiconductor element during application of force. In other exemplary embodiments of the invention, methods of detecting if a crack is present in a semiconductor element include monitoring an electrical characteristic(s) related to ultrasonic energy (e.g., impedance monitoring) applied during a wire bonding operation. In other exemplary embodiments of the invention, methods of detecting if a crack is present in a semiconductor element utilize imaging systems (e.g., imaging a portion of the semiconductor element before and/or after formation of a wire bond on the portion of the semiconductor element). These, and other methods within the scope of the invention, may be combined as desired (e.g., deflection measurement combined with imaging system detection; deflection measurement combined with monitoring an electrical characteristic; monitoring an electrical characteristic combined with an imaging system; etc.).

Certain methods and systems described herein enable performing an inspection of a semiconductor element (e.g., a semiconductor die) before wire bonds are formed. Such inspections may be for cracks (e.g., “die cracks”) caused by processes that occurred before wire bonding (e.g., wafer back grinding, dicing, die attach, probing, etc.). Further, aspects of the invention also relate to inspection for cracks after a wire bonding operation (e.g., after wire bonds have been formed).

Certain embodiments of the invention detect cracks in real time using a wire bonding system (e.g., a wire bonder, a wire bonding machine, etc.). Certain embodiments use a wire bonding system (e.g., a wire bonder, a wire bonding machine, etc.) to mechanically test the semiconductor elements for cracks before and/or after wire bonding. As described herein, in certain embodiments, ultrasonic based crack detection (e.g., monitoring an electrical characteristic related to ultrasonic energy applied during a wire bonding operation) and image based crack detection (e.g., vision-based, optical, etc.) can be used (e.g., to detect cracks as seen from a top view of the semiconductor element). In certain embodiments, infrared cameras, laser systems, and ultrasonic based non-destructive sensing systems may be used (e.g., as an alternative to, or in addition to, mechanical detection mechanisms) for crack detection on wire bonding systems.

When a wire bonding tool (e.g., carried by a bond head assembly of a wire bonding machine) makes contact with a bond pad (or other bonding location) on an unsupported portion of an overhanging die (or another overhanging portion of a semiconductor element), the die surface may deflect downwards. This deflection may cause a number of issues with wire bonding and/or loop shaping, for example, due to die vibration when the wire bonding tool lifts off of the die surface after bonding. When a “crack” is present in the overhanging die, the defect may be detrimental to an entire semiconductor package or workpiece (e.g., by excessive deflection, die fragmenting, etc.).

Certain aspects of the invention relate to automatically performing an in situ crack detection, a pre-bond crack detection, and/or a post-bond crack detection. In accordance with certain exemplary embodiments of the invention, a bond program is taught with programmed bonding locations (e.g., location on an overhang die). A bonding tool (e.g., a capillary) touches down (e.g., with or without wire engaged in the bonding tool) on each programmed bonding location with pre-defined starting values of certain parameters such as damping gain, contact velocity (e.g., in a constant velocity mode) and bond force. The z-axis encoder is used to provide data (e.g., position values along a vertical “z-axis”) which is then collected and analyzed. The data may be compared with user defined values (e.g., allowable die deflection, desired bond force, etc.) to determine if a crack is present.

Sometimes, a die crack may present itself as a microcrack, which is not obvious at the processing stage and may be difficult to detect. Ordinarily, such microcracks may not be detectable until a later functional test is performed. In certain instances, the semiconductor element fails during the eventual functional testing of the package or end product (e.g., after encapsulation). Currently, functional testing is done in an “offline” and cumbersome process. When microcracks are not detected and failures occur during functional device testing, an entire production lot may be rejected. Certain embodiments described herein are able to detect a die crack in earlier stages, which can prevent future failures. The ability to detect cracks in situ and/or in real time using a wire bonding system (e.g., a wire bonder) can save time and material, and can greatly improve yield. The methods and systems described herein can be used to develop or optimize processes that can minimize or eliminate crack related issues.

Throughout the drawings, like reference numerals denote like elements. Accordingly, descriptions of certain elements in connection with certain figures may be applicable throughout the drawings, unless the context indicates otherwise.

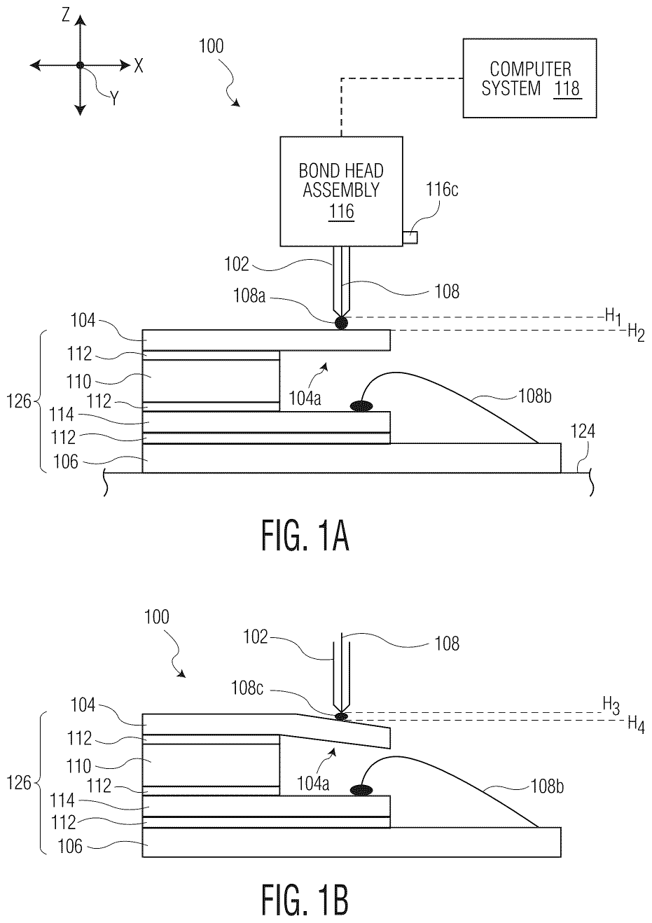

Referring now to the drawings, in FIGS. 1A-1C, a wire bonding system 100 is illustrated. Wire bonding system 100 includes a bond head assembly 116 for bonding one or more wires to a semiconductor element 104 (e.g., a die in a workpiece 126). Bond head assembly 116 is configured to carry a wire bonding tool 102 (e.g., a capillary, a wedge bonding tool, etc.) for performing a wire bonding operation with respect to workpiece 126 including semiconductor element 104. Bond head assembly 116 includes a z-axis encoder 116c to measure a z-axis position (e.g., a vertical position) of bond head assembly 116 of wire bonding system 100. As will be appreciated by those skilled in the art, bond head assembly 116 may include a number of elements configured to travel along multiple axes of wire bonding system 100 (e.g., along a horizontal x-axis, along a horizontal y-axis, along a vertical z-axis, etc.). These elements may include, for example, an ultrasonic transducer, an imaging system, a wire clamp, and various other elements. Z-axis encoder 116c may be positioned as desired on bond head assembly 116.

Wire bonding system 100 also includes a support structure 124 for supporting workpiece 126 (including semiconductor element 104). Wire bonding system 100 also includes a computer system 118. Computer system 118 may be configured to control the motion of bond head assembly 116. Computer system 118 may also be configured to detect if there is a crack in semiconductor element 104 (e.g., and/or a semiconductor element 114, etc.) on wire bonding system 100. In certain embodiments, computer system 118 may be configured to determine a z-axis position of a portion (e.g., a deflected portion) of the semiconductor element to detect if there is a crack in the semiconductor element. In certain embodiments, computer system 118 may be configured to communicate with an imaging system (e.g., an imaging system carried by bond head assembly 116) to detect if there is a crack in the semiconductor element. In certain embodiments, computer system 118 may be configured to monitor an electrical characteristic (e.g., an impedance value) related to ultrasonic energy applied during a wire bonding operation.

Thus, at least in connection with computer system 118, wire bonding system 100 is configured to detect if there is a crack in semiconductor element 104 (e.g., and/or a semiconductor element 114, etc.) on wire bonding system 100. As will be appreciated by those skilled in the art, computer system 118 may be any type of computing device (e.g., a controller, a computer included as part of wire bonding system 100, a computer system remote from wire bonding system 100, multiple computing devices such as processors working in connection with wire bonding system 100, etc.).

In FIGS. 1A-1C, workpiece 126 is illustrated disposed on support structure 124. Workpiece 126 is an example workpiece; however, it is understood that the invention is not limited for use in connection with any specific workpiece. The invention has broad applicability across a wide variety of workpiece types. The illustrated workpiece 126 includes a substrate 106 disposed directly on support structure 124. Semiconductor element 114 (e.g., a “bottom die”) is illustrated disposed on substrate 106 using an adhesive 112 (e.g., a die attach adhesive). A spacer 110 is illustrated disposed on semiconductor element 114 using adhesive 112. Semiconductor element 104 (e.g., a “top die”) is illustrated disposed on spacer 110 using adhesive 112.

Referring specifically to FIG. 1A, a free air ball 108a (i.e., a FAB) is illustrated provided at the end of bonding tool 102 (e.g., a capillary) at height H₁ (e.g., a height with respect to a reference line on wire bonding system 100) prior to a wire bonding operation. Free air ball 108a is formed from a wire 108 (where wire 108 is disposed through bonding tool 102). Free air ball 108a is in contact with a portion (e.g., a top surface) of semiconductor element 104 (where the top surface of semiconductor element 104 is shown at a height H₂, another height with respect to a reference line). Semiconductor element 104 is illustrated in an “overhang” state, where an unsupported portion 104a of semiconductor element 104 is not directly supported underneath. Underneath semiconductor element 104, a wire loop 108b is illustrated.

Referring now to FIG. 1B, wire bonding tool 102 is illustrated having been moved downward (i.e., along the vertical z-axis direction) by applying a predetermined force in connection with a wire bonding operation (e.g., a wire loop forming operation). In FIG. 1B (and certain other drawings herein) certain structures of wire bonding system 100 have been omitted for simplicity (e.g., bond head assembly 116, support structure 124, computer system 118, etc.). Free air ball 108a is illustrated in a deformed state as first bond 108c (or a squash in certain applications). The end of wire bonding tool 102, having been moved downward, is now at height H₃, where H₃ is lower (i.e., closer to substrate 106) than H₁. With the end of wire bonding tool 102 at height H₃, the top surface of semiconductor element 104 is now at height H₄, where H₄ is lower (i.e., closer to substrate 106) than H₂. That is, as a result of a force being applied in connection with a wire bonding operation, the unsupported portion 104a of semiconductor element 104 is illustrated in a deformed, altered, or bent state.

Referring now to FIG. 1C, wire bonding tool 102 is illustrated having been moved even further downward (i.e., along the vertical z-axis direction). Unsupported portion 104a is illustrated having been cracked, thereby forming unsupported portion 104a′ and fractured portion 104a″. Of course, it should be understood that this illustration is not to scale. Fractured portion 104a″ may not completely separate from the other portions of semiconductor element 104. The end of wire bonding tool 102, having been moved downward, is now at height H₅, where H₅ is lower (i.e., closer to substrate 106) than H₁ and H₃. With the end of wire bonding tool 102 at height H₅, the top surface of semiconductor element 104 is now at height H₆, where H₆ is lower (i.e., closer to substrate 106) than H₂ and H₄. A threshold value for the height of wire bonding tool 102, and/or a height of the top surface of the semiconductor element 104, may be used to determine if there is a crack in semiconductor element 104. For example, suppose that any height of wire bonding tool 102 lower than height H₃ indicates the presence of a crack in semiconductor element 104. Since height H₅ is lower than H₃, wire bonding tool 102 reaching height H₅ may be used to detect a crack in semiconductor element 104. For example, suppose that any height of the top surface of semiconductor element 104 that is lower than height H₄ indicates the presence of a crack in semiconductor element 104. Since height H₆ is lower than H₄, the top surface of semiconductor element 104 reaching height H₆ may be used to detect a crack in semiconductor element 104. Of course, these are just examples of how to detect a crack in semiconductor element 104 using the deflection of an unsupported portion of semiconductor element 104.

Further, while FIGS. 1A-1C illustrate height values with respect to certain locations (e.g., an end of bonding tool 102, a top surface of semiconductor element 104), it is understood that these are simply examples of height values that may be monitored in connection with crack detection. In accordance with the invention, any suitable height value may be monitored in connection with crack detection.

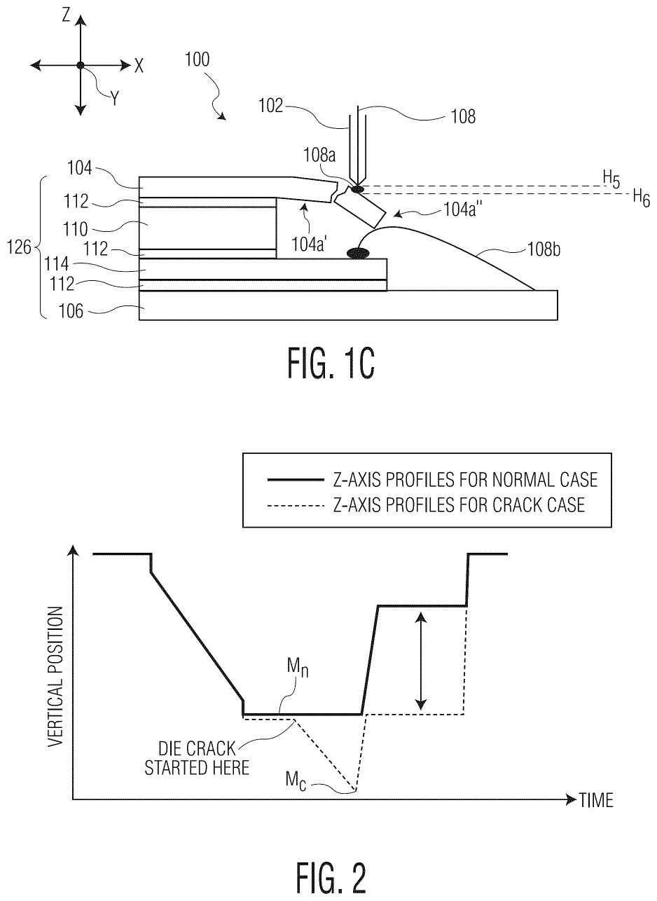

Referring now to FIG. 2, a plot of the vertical position of wire bonding tool 102 in connection with a crack detection operation (in this case, coinciding with a wire bonding operation) is illustrated. As illustrated, the z-axis profile of wire bonding tool 102 when a crack is present (e.g., from before the bonding operation; resulting from the bonding operation; etc.) is distinguishable from the z-axis profile without a crack (i.e., a “normal” case). For example, there is a discernible difference in the minimum value, Mc, in a crack-present case as compared to the minimum value, Mn, in a “normal” case.

In addition to a comparison of measured height values (e.g., H₅ and/or H₆ of FIG. 1C) to the threshold values (e.g., H₃ and/or H₄ of FIG. 1B), cracks can be detected as a function of the vertical position profile as a function of time. For example, a crack can be detected if the semiconductor element is bending or yielding at a greater rate than expected (e.g., but before reaching a “threshold” value). For example, with respect to FIG. 2, the slope of the profile as the bonding tool deforms the semiconductor element could be compared to a reference slope to determine if a crack is present in the semiconductor element.

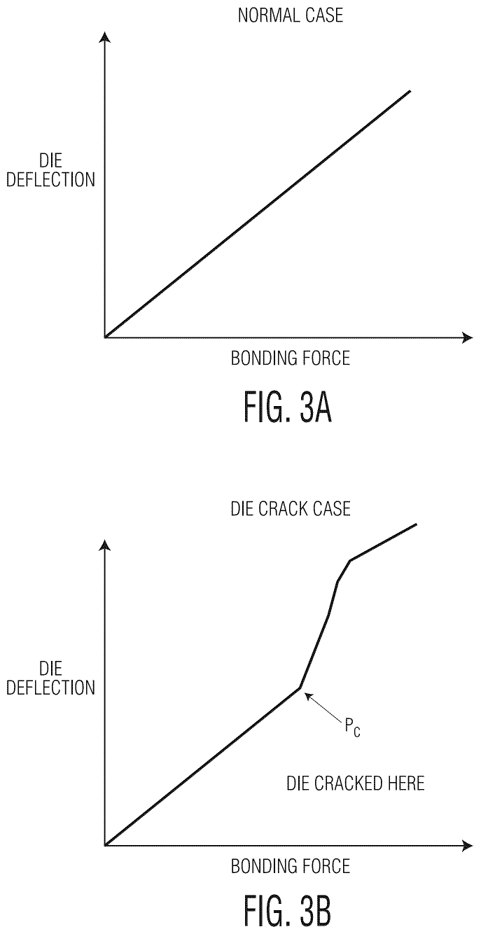

Referring now to FIGS. 3A-3B, plots of the deflection of a semiconductor element (e.g., a semiconductor die) as a function of force in connection with a crack detection operation (in this case, coinciding with a wire bonding operation) are illustrated. Referring specifically to FIG. 3A, an exemplary “normal” crack detection operation (and wire bonding operation) is illustrated. As illustrated, the deflection of the semiconductor element (e.g., semiconductor element 104 of FIGS. 1A-1B) has a generally linear relationship, where the amount of deflection is proportional to the applied force (e.g., applied using a wire bonding tool). It should be understood that the linear shape of FIG. 3A is an approximation. In certain configurations or applications, the relationship may be non-linear (e.g., an exponential function, a logarithmic function, a polynomial function, etc.). Nevertheless, this relationship can be considered as a baseline (or as an expected relationship), from which the presence of a crack can be determined (e.g., when a certain deviation from the expected relationship manifests).

Referring specifically to FIG. 3B, a crack detection operation (and coinciding with a wire bonding operation), where a crack is present, is illustrated. As illustrated, the semiconductor element and applied force (e.g., labelled “bonding force”) relationship is linear and constant from the origin until reaching the crack point Pc (e.g., see FIG. 1C, where a crack is present). At Pc, the semiconductor element cracks and/or yields, and thereafter, the semiconductor element deflects at a greater rate as a function of increased force. Thus, a crack can be detected (e.g., using computer system 118).

Wire bonding system 100 can be configured to detect cracks using a number of different techniques. For example, in certain embodiments, the crack detection can be accomplished using computer system 118 in connection with bonding tool 102 carried by bond head assembly 116 (e.g., see FIGS. 1A-1C). In certain embodiments, another contact element or device can be used in connection with the crack detection. In certain embodiments, an imaging system (e.g., a camera and illumination assembly) can be used in connection with the crack detection. In certain embodiments, a combination of an imaging system, a bonding tool, and/or a contact element can be used in connection with the crack detection.

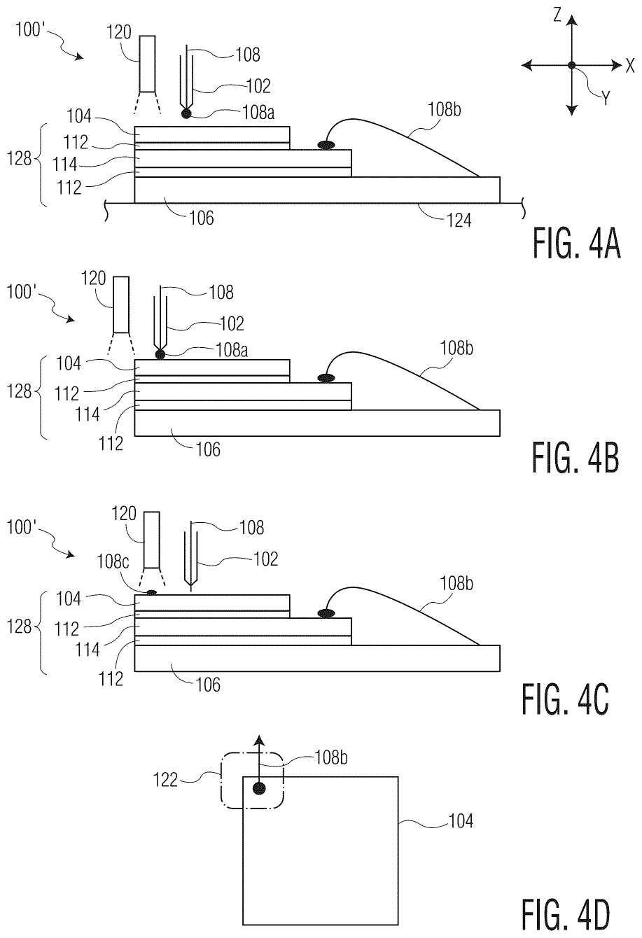

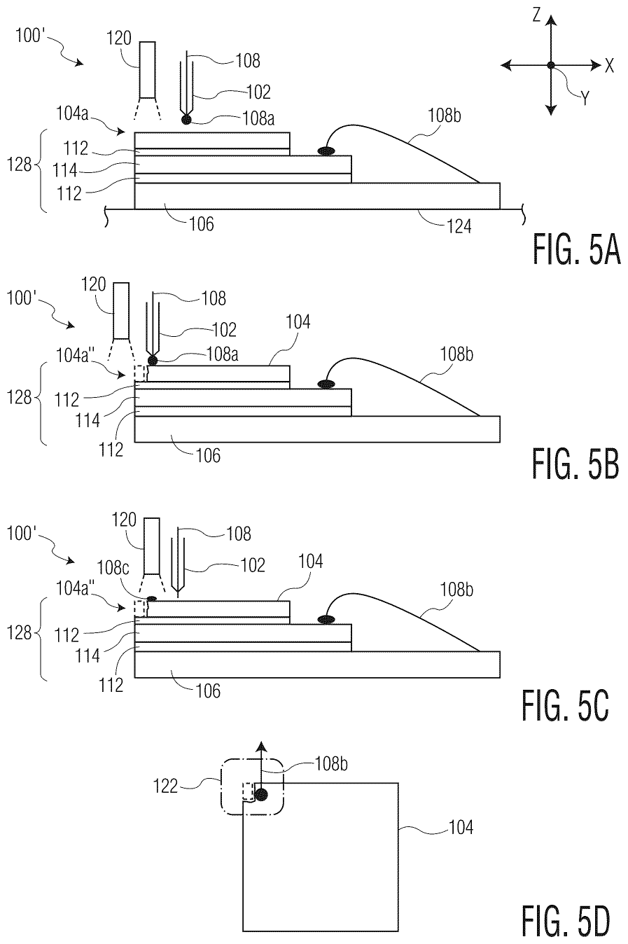

Referring now to FIGS. 4A-4D and FIGS. 5A-5D, a wire bonding system 100′ is illustrated. The description of wire bonding system 100 in connection with FIGS. 1A-1C is applicable to wire bonding system 100′, except where indicated otherwise. Wire bonding system 100′ is substantially the same as wire bonding system 100, except wire bonding system 100′ includes an imaging system 120. It should be noted that certain structures of wire bonding system 100′ have been omitted for simplicity (e.g., bond head assembly 116, support structure 124, computer system 118, etc.) in certain figures.

FIGS. 4A-4D and FIGS. 5A-5D illustrate a “non-overhang” configuration of semiconductor elements 104/114 and substrate 106 (in contrast to the application illustrated in FIGS. 1A-1C). In FIGS. 4A-4D and FIGS. 5A-5D, a workpiece 128 is illustrated on support structure 124 (not illustrated in FIGS. 4B-4D and FIGS. 5B-5D). Semiconductor element 114 (e.g., a “bottom die”) is illustrated disposed on substrate 106 using adhesive 112 (e.g., a die attach adhesive). Semiconductor element 104 (e.g., a “top die”) is illustrated disposed on semiconductor element 114 using adhesive 112.

FIGS. 4A-4D illustrate the use of an imaging system 120 in connection with an application where a crack was not detected. A bond head assembly (e.g., bond head assembly 116, another bond head assembly, etc.) can be configured to carry imaging system 120, where imaging system 120 is used in connection with detecting if there is a crack in a semiconductor element (e.g., semiconductor element 104). In certain embodiments, imaging system 120 is not carried by the bond head assembly (not illustrated), where imaging system 120 is configured to perform an imaging operation on wire bonding system 100′ in connection with detecting if there is a crack in a semiconductor element (e.g., semiconductor element 104). In certain embodiments, imaging system 120 is configured for imaging a portion of a semiconductor element (e.g., semiconductor element 104) before formation of a wire bond on the semiconductor element and after formation of the wire bond on the semiconductor element.

Referring now to FIG. 4A, a free air ball 108a (i.e., a FAB) is illustrated at the end of bonding tool 102 (e.g., a capillary) prior to a wire bonding operation. In FIG. 4A, imaging system 120 may optionally provide one or more images of semiconductor element 104 (in connection with computer system 118, not illustrated) prior to the wire bonding operation. Such image(s) may be used in a comparison to an image(s) taken after a wire bonding operation (e.g., see FIG. 4C, and description below), in connection with a crack detection process. At FIG. 4B, free air ball 108a is brought into contact with the top surface of semiconductor element 104 prior to a wire bonding operation. During the wire bonding operation, imaging system 120 (in connection with data processing hardware, such as computer system 118 shown in FIG. 1A, and associated software) can provide images to assess crack detection in real time. At FIG. 4C, a first bond 108c (or a squash) is illustrated having been formed (where a full wire loop, similar to wire loop 108b in FIG. 4D, may be formed using first bond 108c). Bond head assembly (not illustrated) has been moved to the right (i.e., the horizontal or +X direction), thereby moving wire bonding tool 102 and imaging system 120. FIG. 4C illustrates imaging system 120 providing an image(s) 122 (e.g., of FIG. 4D) in connection with computer system 118 (not illustrated) after the wire bonding operation. As illustrated in the top view of FIG. 4D, image 122 does not illustrate a crack. Thus, wire bonding system 100′ can determine that a crack is not present (and/or was not detected). This determination can be done automatically (e.g., using computer system 118). The captured image 122 can be recorded and displayed to an operator (e.g., a machine operator, an engineer, etc.). This crack detection process may utilize images taken prior to the wire bonding operation (e.g., see FIG. 4A, and description above) and images taken after the wire bonding operation, or may simply utilize images taken after the wire bonding operation.

FIGS. 5A-5D illustrate the use of imaging system 120 in connection with an application where a crack was detected. Referring now to FIG. 5A, a free air ball 108a (i.e., a FAB) is provided at the end of bonding tool 102 (e.g., a capillary) prior to a wire bonding operation. In FIG. 5A, imaging system 120 may optionally provide one or more images of semiconductor element (in connection with computer system 118, not illustrated) prior to the wire bonding operation. Such image(s) may be used in a comparison to an image(s) taken after a wire bonding operation (e.g., see FIG. 5C, and description below), in connection with a crack detection process. At FIG. 5B, free ball 108a is brought into contact with the top surface of semiconductor element 104 in connection with a wire bonding operation. During the wire bonding operation, imaging system 120 (in connection with data processing hardware, such as computer system 118 shown in FIG. 1A, and associated software) can provide images to assess crack detection in real time. During the bonding operation, a crack manifested, as illustrated by fractured portion 104a″. At FIG. 5C, a first bond 108c (or a squash) is illustrated having been formed (where a full wire loop, similar to wire loop 108b in FIG. 5D, may be formed using first bond 108c). Bond head assembly (not illustrated) has been moved to the right (i.e., the horizontal or +X direction), thereby moving wire bonding tool 102 and imaging system 120. FIG. 5C illustrates imaging system 120 providing an image(s) 122 (e.g., of FIG. 5D) in connection with computer system 118 (not illustrated) after the wire bonding operation. As illustrated in the top view of FIG. 5D, image 122 does illustrate a crack. Thus, wire bonding system 100′ can determine that a crack is present. This determination can be done automatically (e.g., using computer system 118). The captured image 122 can be recorded and displayed to an operator (e.g., a machine operator, an engineer, etc.). This crack detection process may utilize images taken prior to the wire bonding operation (e.g., see FIG. 5A, and description above) and images taken after the wire bonding operation, or may simply utilize images taken after the wire bonding operation.

It should be understood that imaging system 120 can include a number of embodiments. For example, imaging system 120 can include an optical camera using visible light. In another example, imaging system 120 can include an infrared camera. In another example, imaging system 120 can include a laser system. In another example, imaging system can use electromagnetic radiation which can penetrate the semiconductor element (e.g., using x-rays and the like).

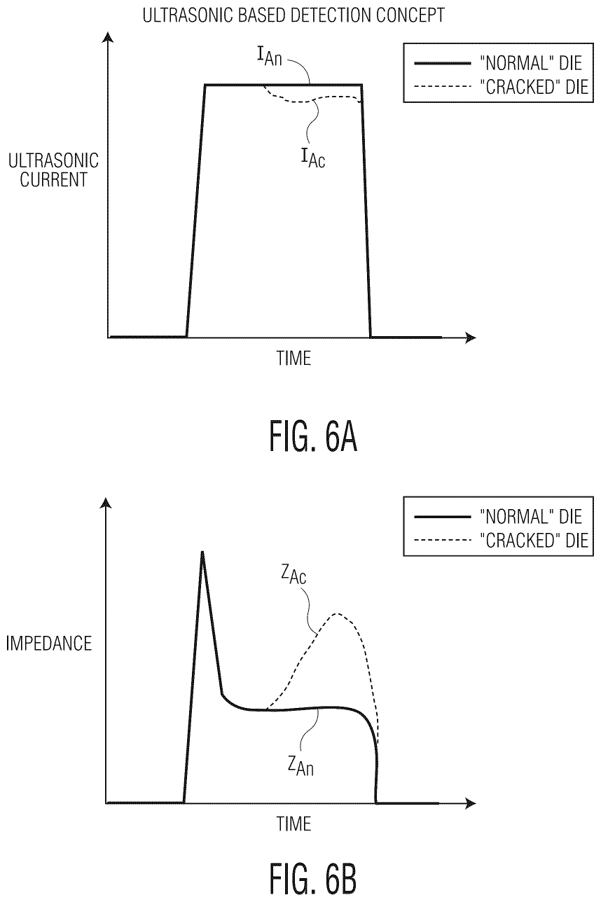

Referring now to FIGS. 6A-6B, exemplary plots of electrical characteristics, in connection with ultrasonic based detection, are illustrated. Referring to FIG. 6A, a plot of ultrasonic current as a function of time is illustrated. The ultrasonic current applied (e.g., to a transducer of a bond head assembly) in a “normal” operation (i.e., where the semiconductor element is not cracked) is designated with the reference characters I_{An}. The ultrasonic current applied when the semiconductor element is cracked (or contains a crack) is designated with the reference characters I_{Ac}. As illustrated, the applied current I_{Ac} fluctuates during a wire bonding operation when a crack is present. In contrast, applied current I_{An} remains relatively constant throughout a wire bonding operation when a crack is not present. Such current information can be used in a crack detection process (e.g., using computer system 118).

Referring to FIG. 6B, an exemplary plot of impedance as a function of time is illustrated. The impedance (e.g., to a transducer of a bond head assembly) in a “normal” operation (i.e., where the semiconductor element is not cracked) is designated with the reference characters Z_{An}. The impedance when the semiconductor element is cracked is designated with the reference characters Z_{Ac}. As illustrated, the impedance Z_{Ac} fluctuates in the presence of a crack (e.g., due to a discontinuous surface at the bonding location) during a wire bonding operation. In contrast, applied current Z_{An} remains relatively constant throughout a wire bonding operation (designated by the relatively flat portion of the plot labelled with Z_{An}). Such impedance information can be used in a crack detection process (e.g., using computer system 118).

As illustrated in FIG. 6A-6B, either the ultrasonic current or impedance (or both) can be used to detect the presence of a crack (e.g., during a wire bonding operation). It should be understood that other electrical characteristics (e.g., voltage) may be used for crack detection.

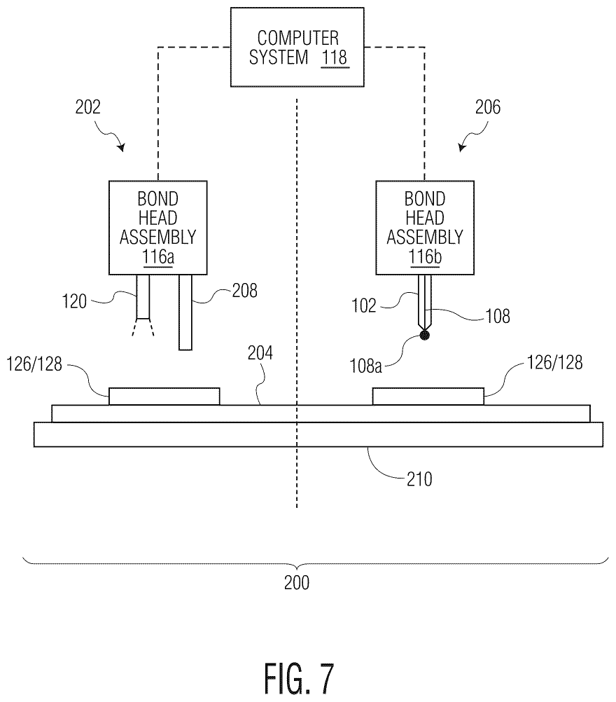

Referring now to FIG. 7, a wire bonding system 200 is illustrated. Wire bonding system 200 includes a crack detection system 202 and a wire bonding system 206. Wire bonding system 200 also includes a support structure 210 for supporting a workpiece (e.g., a substrate, a semiconductor element, a die, etc.) and a material handling system 204. Crack detection system 202 includes a bond head assembly 116a, including an imaging system 120. Bond head assembly 116a is configured to carry imaging system 120 used in connection with detecting if there is a crack in a semiconductor element (e.g., similar to the techniques illustrated and described in connection with FIGS. 4A-4D and FIGS. 5A-5D). Bond head assembly 116a is configured to support and/or carry a contact tool 208. Contact tool 208 may be a bonding tool (e.g., a capillary) or another tool (e.g., a contact element which is not a bonding tool). Contact tool 208 can be used in connection with detecting if there is a crack in a semiconductor element (e.g., similar to the techniques illustrated and described in connection with FIGS. 1A-1C).

Wire bonding system 206 includes bond head assembly 116b, which is illustrated supporting bonding tool 102. Wire bonding system 206 is similar in many ways to wire bonding system 100 of FIGS. 1A-1C. Accordingly, much of the description of wire bonding system 100 is applicable to wire bonding system 206, except where indicated otherwise (or where the context makes the differences clear). For example, bond head assembly 116b is similar to bond head assembly 116 (i.e., of FIGS. 1A-1C).

Bond head assembly 116a and bond head assembly 116b can be located in a common area, or in separate areas (e.g., separate compartments), as illustrated by the vertical dashed line. Material handling system 204 can move workpiece 126/128 (including semiconductor element 104) from crack detection system 202 to wire bonding system 206. In one example, after workpiece 126/128 is indicated to have “passed” a crack detection test (e.g., using one or more of imaging system 120, contact tool 208, or another process described herein), workpiece 126/128 can be moved to wire bonding system 206 for a wire bonding operation. Bond head assemblies 116a and 116b can be electronically and communicatively coupled to computer system 118. Thus, computer system 118 can instruct bond head assembly 116b to not bond a semiconductor element 104 (e.g., of workpiece 126/128) if a crack is detected.

It should be understood that a number of embodiments of the system illustrated in FIG. 7 are contemplated. For example, a plurality of imaging systems 120 can be used (e.g., at least one imaging system 120 in crack detection system 202 for pre-bonding operations, and at least one imaging system 120 in wire bonding system 206 for bonding and post-bonding operations).

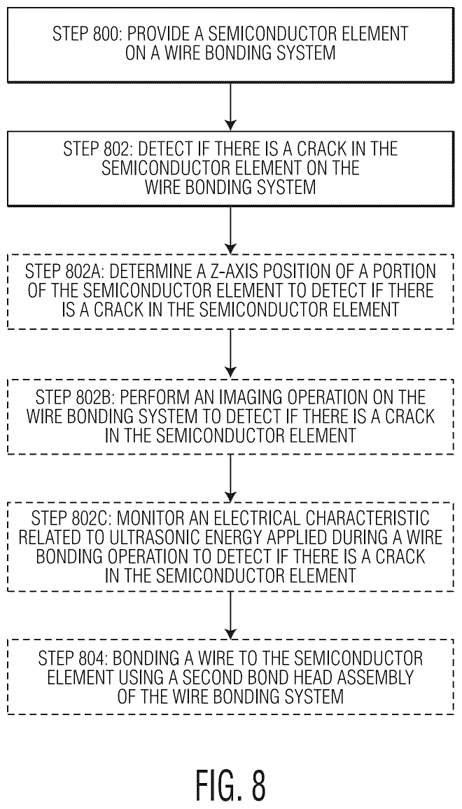

FIG. 8 is a flow diagram illustrating a method of detecting a crack in a semiconductor element on a wire bonding system. As is understood by those skilled in the art, certain steps included in the flow diagram may be omitted; certain additional steps may be added; and the order of the steps may be altered from the order illustrated-all within the scope of the invention.

At Step 800, a semiconductor element is provided on a wire bonding system (e.g., wire bonding system 100 of FIGS. 1A-1C). At Step 802, a detection (e.g., a determination) is made as to whether there is a crack in the semiconductor element on the wire bonding system. At optional Step 802A (which may be part of Step 802), a z-axis position of a portion (e.g., a deflected portion) of the semiconductor element (e.g., during a wire bonding operation) is determined to detect if there is a crack in the semiconductor element (e.g., see FIGS. 1A-1C, FIG. 2, and FIGS. 3A-3B). At optional Step 802B (which may be part of Step 802), an imaging operation is performed on the wire bonding system to detect if there is a crack in the semiconductor element (e.g., see FIGS. 4A-4D and FIGS. 5A-5D). In certain embodiments, the imaging operation includes imaging of a portion of the semiconductor element before formation of a wire bond on the semiconductor element, and after formation of the wire bond on the semiconductor element. At optional Step 802C (which may be part of Step 802), an electrical characteristic, related to ultrasonic energy applied during a wire bonding operation, is monitored to detect if there is a crack in the semiconductor element (e.g., see FIGS. 6A-6B). In certain embodiments, the electrical characteristic is an impedance value related to operation of an ultrasonic transducer. It should be understood that any of Steps 802A, 802B, or 802C can be used (separately or in combination) in the detection of a crack. At Step 804, a wire is bonded to the semiconductor element using a second bond head assembly of the wire bonding system (e.g., see wire loop 108b of FIG. 4D and FIG. 5D), wherein Step 802 includes detecting if there is a crack in the semiconductor element using a first bond head assembly of the wire bonding system. In certain embodiments, Step 802 includes contacting a deflected portion of the semiconductor element with a contact tool carried by the first bond head assembly to detect if there is a crack in the semiconductor element.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method of detecting a crack in a semiconductor element on a wire bonding system, the method comprising the steps of:
(a) providing the semiconductor element on the wire bonding system; and
(b) detecting if there is a crack in the semiconductor element on the wire bonding system.

2. The method of claim 1 wherein step (b) includes determining a z-axis position of a portion of the semiconductor element to detect if there is a crack in the semiconductor element.

3. The method of claim 2 wherein step (b) includes performing an imaging operation on the wire bonding system to detect if there is a crack in the semiconductor element.

4. The method of claim 1 wherein step (b) includes determining a z-axis position of a deflected portion of the semiconductor element to detect if there is a crack in the semiconductor element.

5. The method of claim 1 wherein step (b) includes determining a z-axis position of a portion of the semiconductor element during a wire bonding operation to detect if there is a crack in the semiconductor element.

6. The method of claim 1 wherein step (b) includes performing an imaging operation on the wire bonding system to detect if there is a crack in the semiconductor element.

7. The method of claim 6 wherein the imaging operation includes imaging of a portion of the semiconductor element (i) before formation of a wire bond on the semiconductor element, and (ii) after formation of the wire bond on the semiconductor element.

8. The method of claim 1 wherein step (b) includes monitoring an electrical characteristic related to ultrasonic energy applied during a wire bonding operation to detect if there is a crack in the semiconductor element.

9. The method of claim 8 wherein the electrical characteristic is an impedance value related to operation of an ultrasonic transducer.

10. The method of claim 1 wherein step (b) includes detecting if there is a crack in the semiconductor element using a first bond head assembly of the wire bonding system, the method further comprising the step of (c) bonding a wire to the semiconductor element using a second bond head assembly of the wire bonding system.

11. The method of claim 10 wherein step (b) includes contacting a deflected portion of the semiconductor element with a contact tool carried by the first bond head assembly to detect if there is a crack in the semiconductor element.

12. A wire bonding system comprising:
a bond head assembly configured for carrying a wire bonding tool for performing a wire bonding operation with respect to a workpiece including a semiconductor element;
a support structure for supporting the workpiece; and
a computer system, the computer system being configured to detect if there is a crack in the semiconductor element on the wire bonding system.

13. The wire bonding system of claim 12, further comprising another bond head assembly, wherein the another bond head assembly is configured to carry a contact tool used in connection with detecting if there is a crack in the semiconductor element.

14. The wire bonding system of claim 12, further comprising another bond head assembly, wherein the another bond head assembly is configured to carry an imaging system used in connection with detecting if there is a crack in the semiconductor element.

15. The wire bonding system of claim 12 wherein the computer system is configured to determine a z-axis position of a portion of the semiconductor element to detect if there is a crack in the semiconductor element.

16. The wire bonding system of claim 12 further comprising an imaging system attached to the bond head assembly, wherein the imaging system is configured to perform an imaging operation on the wire bonding system in connection with detecting if there is a crack in the semiconductor element.

17. The wire bonding system of claim 16 wherein the imaging system is configured for imaging a portion of the semiconductor element (i) before formation of a wire bond on the semiconductor element, and (ii) after formation of the wire bond on the semiconductor element.

18. The wire bonding system of claim 12 wherein the computer system is configured to determine a z-axis position of a deflected portion of the semiconductor element to detect if there is a crack in the semiconductor element.

19. The wire bonding system of claim 12 wherein the computer system is configured to determine a z-axis position of a portion of the semiconductor element during a wire bonding operation to detect if there is a crack in the semiconductor element.

20. The wire bonding system of claim 12 wherein the computer system is configured to monitor an electrical characteristic related to ultrasonic energy applied during a wire bonding operation.

21. The wire bonding system of claim 20 wherein the electrical characteristic is an impedance value related to operation of an ultrasonic transducer.
